(19) United States
(12) Patent Application Publication
(10) Pub. No.: US 2026/0114272 A1
(43) Pub. Date: Apr. 23, 2026

(54) THERMAL SOLUTIONS FOR ARTIFICIAL INTELLIGENCE CHIPLET MODULES

(71) Applicant: INTERNATIONAL BUSINESS MACHINES CORPORATION, ARMONK, NY (US)

(72) Inventors: John Knickerbocker, Monroe, NY (US); Mukta Ghate Farooq, Hopewell Junction, NY (US); John W. Golz, Hopewell Junction, NY (US); Keiji Matsumoto, Yokohama-shi (JP)

(21) Appl. No.: 18/923,802

(22) Filed: Oct. 23, 2024

(51) Int. Cl. H01L 23/367; H01L 23/00; H01L 23/42; H01L 23/48; H01L 23/538; H01L 25/18; H10B 80/00

(52) U.S. Cl. CPC H10W 40/22; H10W 20/20; H10W 40/70; H10W 70/611; H10W 90/00; H10W 90/401; H10B 80/00; H10W 72/07254; H10W 72/247; H10W 72/877; H10W 90/723; H10W 90/724; H10W 90/731

(57) ABSTRACT

An apparatus including a substrate having a first surface, and a silicon interposer including a first surface and a second surface, wherein the first surface is connected to the first surface of the substrate. The apparatus also includes at least one stack including an artificial intelligence (AI) chiplet and a plurality of static random-access memories (SRAMs) stacked below the AI chiplet, wherein the at least one stack includes a top surface, a bottom surface, a first side surface and a second side surface, and the at least one stack is orthogonally attached by the first side surface to the second surface of the silicon interposer. The apparatus additionally includes a heat spreader surrounding the top surface, the bottom surface and the second side surface of the at least one stack.

### BACKGROUND

The present disclosure generally relates to semiconductor device packaging, and more particularly to thermal management of semiconductor devices.

Integrated circuits (“ICs”) are incorporated into many electronic devices. Integrated circuit (IC) packaging allows for multiple ICs to be vertically stacked in three-dimensional (3D) packages in order to save horizontal area on printed circuit boards (PCBs).

One consideration of semiconductor device packaging is thermal management. As semiconductor devices are operating, heat is generated. Different thermal characteristics of multiple structures and their different materials can result in dimensional changes and performance variations when subjected to temperature changes.

### SUMMARY

According to some embodiments of the disclosure, there is provided an apparatus including a substrate having a first surface. The apparatus also includes a silicon interposer including a first surface and a second surface, wherein the first surface is connected to the first surface of the substrate. The apparatus further includes at least one stack including an artificial intelligence (AI) chiplet and a plurality of static random-access memories (SRAMs) stacked below the AI chiplet, wherein the at least one stack includes a top surface, a bottom surface, a first side surface and a second side surface, and the at least one stack is orthogonally attached by the first side surface to the second surface of the silicon interposer. The apparatus additionally includes a heat spreader surrounding the top surface, the bottom surface and the second side surface of the at least one stack.

According to some embodiments of the disclosure, there is provided an apparatus including a substrate having a first surface. The apparatus also includes a silicon interposer including a first surface and a second surface, wherein the first surface is connected to the first surface of the substrate. The apparatus further includes a plurality of artificial intelligence (AI) chiplets including a first surface and a second surface, wherein the first surface is connected to the second surface of the silicon interposer. The apparatus additionally includes at least two stacks including a plurality of static random-access memories (SRAMs), wherein the at least two stacks include a top surface, a bottom surface, a first side surface and a second side surface, and the at least two stacks are orthogonally attached by the first side surface to the second surface of the plurality of AI chiplets. The apparatus also includes a heat spreader surrounding the top surface, the bottom surface and the second side surface of the at least two stacks.

According to some embodiments of the disclosure, there is provided an apparatus including a substrate having a first surface. The apparatus also includes a silicon interposer including a first surface and a second surface, wherein the first surface is connected to the first surface of the substrate. The apparatus further includes a plurality of artificial intelligence (AI) chiplets including a first surface and a second surface, wherein the first surface is connected to the second surface of the silicon interposer. The apparatus additionally includes at least two stacks including a plurality of static random-access memories (SRAMs), wherein the at least two stacks are divided into two portions that include a top surface, a bottom surface, a first side surface and a second side surface, and the two portions of the at least two stacks are attached by the first side surface to the second surface of the plurality of AI chiplets. The apparatus also includes a heat spreader surrounding the top surface, the bottom surface and the second side surface of the two portions of the at least two stacks.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a side cross-sectional view of an AI chiplet module with heat spreader, in accordance with embodiments of the present disclosure.

FIG. 2 illustrates a side cross-sectional view of an AI chiplet module with heat spreader, in accordance with embodiments of the present disclosure.

FIG. 3 illustrates a side cross-sectional view of an AI chiplet module with heat spreader, in accordance with embodiments of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to thermal regulation of semiconductors. More particularly, the present disclosure provides an apparatus, including an artificial intelligence (AI) chiplet module, in which a heat spreader can come into direct contact with AI chiplets and/or an increased area of stacked internal memory in the module in order to provide efficient thermal management. While the present disclosure is not necessarily limited to such applications, various aspects of the disclosure can be appreciated through a discussion of various examples using this context.

In accordance with embodiments of the present disclosure, devices and methods are described herein that can provide thermal management for stacked semiconductor device structures, such as, e.g., chiplets. A “chiplet” is an integrated circuit (IC) that contains a subset of functionality and can be designed to work with other similar chiplets to form a larger more complex chip. Chiplets can be segmented processors, such as graphics processor units (GPUs) or central processing units (CPUs). It has been determined that it can be difficult to effectively cool a center of stacked semiconductor device structures. A stacked semiconductor device structure, e.g., three-dimensional integrated circuit (3DIC), can be built by vertically stacking different chips or wafers together into a single package.

Three-dimensional (3D) chip stacks are receiving more attention for system performance enhancements. However, because of higher circuit density, cooling of 3D chip stacks gets more challenging. In conventional cooling methods, a heat sink or a micro-channel cooler is located at the top of the chip to dissipate the generated heat in the chip. Thermal management of 3D chip stacks is thereby generally provided by top side thermal management. The thermal or heat spreader can be placed on the top or upper side of a stacked semiconductor device structure. Top side thermal management can be insufficient to cool 3D chip stacks, because it can be difficult for the heat that is generated in lower and middle levels of the stacked semiconductor structure to be transmitted to an upper surface of the stacked semiconductor structure to be dissipated from the structure. In some examples, the heat that is generated in the lower and middle levels can be generated in lower or middle layers of a stacked chiplet or generated in backside power distribution layers (BSPDN).

Artificial intelligence (AI) chiplet modules involve advanced 3D, AI chiplet technology. AI chiplet modules include high capacity and bandwidth stacked internal memory. AI chiplet modules can, therefore, have thermal challenges involving including AI chiplets and/or stacked internal memory, such as static random-access memory (SRAM), for example. Previously, a heat spreader could be added to the tops of AI chiplet modules, which may not effectively provide heat dissipation or removal from the stacked internal memory nor the AI chiplets that generate a lot of heat. In the AI chiplet module of the present disclosure, a heat spreader can come into direct contact with the AI chiplets and/or an increased area of the stacked internal memory in order to provide efficient thermal management.

Embodiments of the present disclosure can solve thermal challenges in AI chiplet modules by positioning a heat spreader, AI chiplets and stacked internal memory such that the heat spreader can come into contact with an increased area of the stacked internal memory and the AI chiplets. The heat spreader can more effectively function to dissipate heat generated by the stacked internal memory and the AI chiplets. Further, the heat spreader can be engaged to more faces of the stacked internal memory and the AI chiplets. For example, the heat spreader can surround a top surface, a bottom surface, and at least one side surface of the stacked internal memory. Embodiments disclosed herein show and describe how heat generated within the stacked internal memory and the AI chiplets can be more effectively dissipated by the heat spreader. In addition, the heat spreader and AI chiplet module structure can advantageously lead to an increase in the application, or use, of the AI chiplet modules.

Embodiments of the present disclosure can include AI chiplet and SRAM stacks, or packages, in which the stacks including the AI chiplet and the SRAMs are orthogonally bonded to a silicon interposer. A heat spreader can surround the AI chiplet and SRAM stacks. Alternatively, a layer of thermal interface material (TIM) can surround the AI chiplets and the SRAM stacks, or portions of stacks, which is then surrounded by the heat spreader.

Embodiments of the present disclosure can include AI chiplets and SRAM stacks in which the size of AI chiplets is increased and the SRAM stacks are orthogonally bonded to the AI chiplets. A heat spreader can directly contact the AI chiplets and the SRAM stacks in such a configuration. Alternatively, a layer of TIM can surround the AI chiplets and the SRAM stacks, which is then surrounded by the heat spreader.

Embodiments of the present disclosure can include AI chiplet and SRAM stacks, or packages, in which the size of the AI chiplet(s) can be increased and the SRAMs can be separated into two parts. A heat spreader can directly contact the AI chiplets and the SRAM stacks. Alternatively, a layer of TIM or adhesive can surround the AI chiplets and the SRAM stacks, or portions of stacks, which is then surrounded by the heat spreader.

Embodiments of the present disclosure include an apparatus including a substrate having a first surface. The apparatus also includes a silicon interposer including a first surface and a second surface, wherein the first surface is connected to the first surface of the substrate. The apparatus further includes at least one stack including an AI chiplet and a plurality of SRAMs stacked below the AI chiplet, wherein the at least one stack includes a top surface, a bottom surface, a first side surface and a second side surface, and the at least one stack is orthogonally attached by the first side surface to the second surface of the silicon interposer. The apparatus additionally includes a heat spreader surrounding the top surface, the bottom surface and the second side surface of the at least one stack.

Embodiments of the present disclosure include an apparatus including a substrate having a first surface. The apparatus also includes a silicon interposer including a first surface and a second surface, wherein the first surface is connected to the first surface of the substrate. The apparatus further includes a plurality of AI chiplets including a first surface and a second surface, wherein the first surface is connected to the second surface of the silicon interposer. The apparatus additionally includes at least two stacks including a plurality of SRAMs, wherein the at least two stacks include a top surface, a bottom surface, a first side surface and a second side surface, and the at least two stacks are orthogonally attached by the first side surface to the second surface of the plurality of AI chiplets. The apparatus also includes a heat spreader surrounding the top surface, the bottom surface and the second side surface of the at least two stacks.

Embodiments of the present disclosure include an apparatus including a substrate having a first surface. The apparatus also includes a silicon interposer including a first surface and a second surface, wherein the first surface is connected to the first surface of the substrate. The apparatus further includes a plurality of AI chiplets including a first surface and a second surface, wherein the first surface is connected to the second surface of the silicon interposer. The apparatus additionally includes at least two stacks including a plurality of SRAMs, wherein the at least two stacks are divided into two portions that include a top surface, a bottom surface, a first side surface and a second side surface, and the two portions of the at least two stacks are attached by the first side surface to the second surface of the plurality of AI chiplets. The apparatus also includes a heat spreader surrounding the top surface, the bottom surface and the second side surface of the two portions of the at least two stacks.

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

As used in this application and in the claims, the singular forms “a,” “an,” and “the” include the plural forms unless the context clearly dictates otherwise. Additionally, the term “includes” means “comprises.”

As used herein, the terms “vertical,” “lateral,” “upper,” “lower,” “up,” “down,” “upstream,” and “downstream” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

The semiconductor devices and methods for forming the same, in accordance with embodiments of the present disclosure, can be employed in applications, hardware, and/or electronic systems. Suitable hardware and systems for implementing embodiments of the invention can include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the disclosure. Given the teachings of embodiments of the disclosure provided herein, one of ordinary skill in the art will be able to contemplate other implementations and applications of embodiments of the disclosure.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

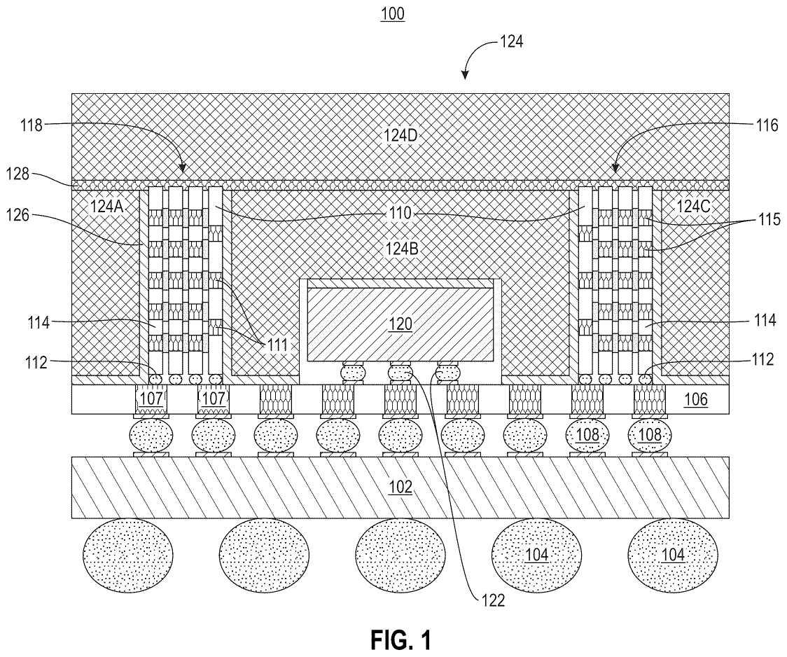

The illustrated embodiments will be best understood by reference to the drawings, where like parts are designated by like numerals throughout. The following description is intended only by way of example, and simply illustrates certain selected embodiments of devices, systems, and processes that are consistent with the embodiments as claimed herein. Referring now to the drawings in which like numerals represent the same or similar elements and initially to FIG. 1, devices and methods for manufacturing a semiconductor device are shown in accordance with embodiments of the present disclosure.

FIG. 1 illustrates a side cross-sectional view of an AI chiplet module with heat spreader 100, in accordance with embodiments of the present disclosure. The AI chiplet module with heat spreader 100 is an example of a semiconductor component, device or module that can be used in an AI accelerator, for example. The AI chiplet module with heat spreader 100 can include an organic substrate 102, as shown, that can serve as a substrate of the AI chiplet module with heat spreader 100. The organic substrate 102 can have an organic composition. It is noted that the organic substrate 102 is not limited to the materials as described above, as other embodiments have also been contemplated. The organic substrate 102 can include a first set of connectors 104, such as in a ball grid array (BGA), on its lower surface that can serve to connect the AI chiplet module with heat spreader 100 to another component or system (not shown).

A silicon interposer 106 is shown located above the organic substrate 102. The silicon interposer 106 can have a semiconductor material composition of silicon or glass, for example. It is noted that the silicon interposer 106 is not limited to the materials as described above, as other embodiments have also been contemplated. In some examples, an interposer structure can be a structure that provides electrical interface routing between one socket or connection to another socket or connection. The purpose of the silicon interposer 106 can be to spread a connection to a wider pitch or to reroute a connection to a different connection. The silicon interposer 106, as shown, includes a plurality of through-silicon vias 107 (TSVs). The TSVs 107 can be made of copper, for example. A second set of connectors 108 can be located between, and provided to connect, the silicon interposer 106 to the organic substrate 102. The connectors 108 can be made of solder, for example. Other materials for the TSVs 107 and the connectors 108 are also contemplated by the disclosure.

On an upper surface of the silicon interposer 106, two (2) AI chiplets 110, each connected to three (3) SRAMS 114, in first and second stacks 116, 118, are orthogonally bonded to the silicon interposer 106. An end of each of the first and second stacks 116, 118 is connected to the silicon interposer 106, such that a horizontal plane running through the length of each of the first and second stacks 116, 118 extends orthogonally (or perpendicular) to the horizontal plane of the silicon interposer 106. A third set of connectors 112 connect the first and the second stacks 116, 118 (via the ends) to the silicone interposer 106. The connectors 112 can be made of solder, for example. Other materials for the connectors 112 are also contemplated by the disclosure. The AI chiplets 110 can include a plurality of TSVs 111, as shown. The AI chiplets 110 generate a lot of heat. As shown, there are a plurality (three (3) shown), or stack, of SRAMs 114. In an example, as shown, three (3) SRAMs 114 can be located atop one (1) of the AI chiplets 110 in order to form a first stack 116 and a second stack 118. The SRAMs 114 can include a plurality of TSVs 115, as shown.

Located between the first and the second stacks 116, 118, there can be a hub 120 that can be connected to the silicon interposer 106 via a fourth set of connectors 122. The connectors 122 can be made of solder, for example. The hub 120 can be a device containing multiple ports that can be connected to several other devices. The hub 120 can be a central device that connects several systems, subsystems, or networks together. The hub 120 can act as a switch that can redirect signals to other components on the AI chiplet module with heat spreader 100 and/or off-module.

A heat spreader 124 surrounds, and can contact, the first and second stacks 116, 118, including the AI chiplets 110 and the SRAMs 114. The heat spreader 124 can be applied or assembled in more than one part or portion. As shown, the heat spreader 124, in one example, can include a first portion 124A, a second portion 124B, a third portion 124C and a fourth portion 124D. The first portion 124A, the second portion 124B and the third portion of a TIM layer 126 being located between both the silicon interposer 106 and the first and second stacks 116, 118 and the first portion 124A, the second portion 124B and the third portion 124C of the heat spreader 124 using a coating process. A layer of high thermal conductivity adhesive 128 (e.g., silver containing adhesive) can be applied atop the first portion 124A of the heat spreader 124 and atop the first and second stacks 116, 118 using a coating process in order to adhere the fourth portion 124D of the heat spreader 124 to upper surfaces of the first portion 124A, the second portion 124B and the third portion 124C of the heat spreader 124 and to an end of each of the first and second stacks 116, 118. Advantageously, the heat spreader 124 (as a whole, including all of the four (4) portions 124A-124D) surrounds a large portion of the first and second stacks 116, 118 in order to remove heat from the first and second stacks 116, 118.

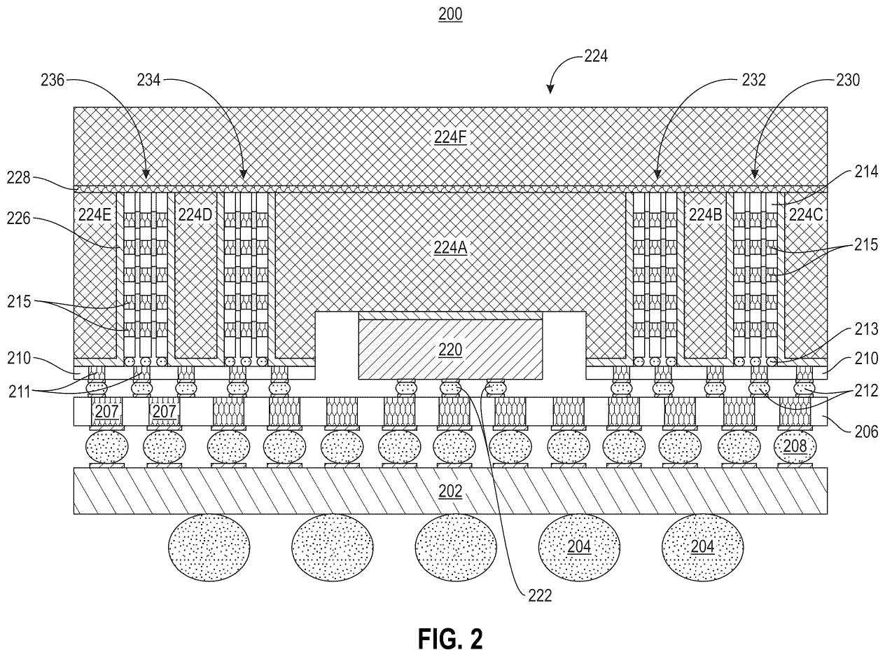

FIG. 2 illustrates a side cross-sectional view of an AI chiplet module with heat spreader 200, in accordance with embodiments of the present disclosure. The AI chiplet module with heat spreader 200 is an example of a semiconductor component, device or module that can be used in an AI accelerator, for example. The AI chiplet module with heat spreader 200 can include an organic substrate 202, as shown, that can serve as a substrate of the AI chiplet module with heat spreader 200. The organic substrate 202 can have an organic composition. It is noted that the organic substrate 202 is not limited to the materials as described above, as other embodiments have also been contemplated. The organic substrate 202 can include a first set of connectors 204, such as in a BGA, on its lower surface that can serve to connect the AI chiplet module with heat spreader 200 to another component (not shown).

A silicon interposer 206 is shown located above the organic substrate 202. The silicon interposer 206 can have a semiconductor material composition of silicon or glass, for example. The organic substrate 202 can have an organic composition. It is noted that the silicon interposer 206 is not limited to the materials as described above, as other embodiments have also been contemplated. The silicon interposer 206 is shown to include a plurality of TSVs 207. The TSVs 207 can be made of copper, for example. A second set of connectors 208 can be located between, and provided to connect, the silicon interposer 206 to the organic substrate 102. The connectors 208 can be made of solder, for example. Other materials for the TSVs 207 and the connectors 208 are also contemplated by the disclosure.

On an upper surface of the silicon interposer 206, two (2) AI chiplets 210 are bonded to the silicon interposer 206 and extend parallel to the silicon interposer 206. The AI chiplets 210 in the AI chiplet module with heat spreader 200 are increased in size, or extended, from the AI chiplets (such as 210) in other embodiments, such as in FIG. 1. The AI chiplets 210 can include TSVs 211, as shown. The AI chiplets 210 generate a lot of heat.

Four (4) memory stacks 230, 232, 234, 236, including three (3) SRAMS 214 each, are arranged orthogonally and ends of the memory stacks 230, 232, 234, 236 are each bonded to an upper surface of one of the two (2) AI chiplets 210 via a third set of connectors 212. The SRAMs 214 can include TSVs 215, as shown. The connectors 212 can be made of solder, for example. Other materials for the connectors 212 are also contemplated by the disclosure. The memory stacks 230, 232, 234, 236 are connected to the AI chiplets 210 such that a horizontal plane running through the length of each of the memory stacks 230, 232, 234, 236 extends orthogonally (or perpendicular) to the horizontal plane of the AI chiplets 210. Between sets of two (2) of the memory stacks 230, 232, 234, 236, there is a hub 220 that can be connected to the silicon interposer 206 via a fourth set of connectors 222. The connectors 222 can be made of solder, for example. The hub 220 can be a device containing multiple ports that can be connected to several other devices. The hub 220 can be a central device that connects several systems, subsystems, or networks together. The hub 220 can act as a switch that can redirect signals to other components on the AI chiplet module with heat spreader 200 and/or off-module. A fifth set of connectors 213 can bond the ends of the memory stacks 230, 232, 234, 236 to the AI chiplets 210.

A heat spreader 224 surrounds and directly contacts the memory stacks 230, 232, 234, 236 including the SRAMs 214. The heat spreader 224 can be applied or assembled in more than one part or portion. As shown, the heat spreader 224, in one example, can include a first portion 224A, a second portion 224B, a third portion 224C, a fourth portion 224D, a fifth portion 224E, and a sixth portion 224F. The first portion 224A, the second portion 224B, the third portion 224C, the fourth portion 224D and the fifth portion 224E of the heat spreader 224 can be applied around the memory stacks 230, 232, 234, 236, with a TIM layer 226 being located between both the AI chiplets 210 and the memory stacks 230, 232, 234, 236 and the first portion, 224A, the second portion 224B, the third portion 224C, the fourth portion 224D and the fifth portion 224E of the heat spreader 224. A layer of high thermal conductivity adhesive 228 (e.g., silver containing adhesive) can be applied by a coating process atop the first portion 224A, the second portion 224B, the third portion 224C, the fourth portion 224D and the fifth portion 224E of the heat spreader 224 and atop upper ends of the memory stacks 230, 232, 234, 236 in order to adhere the sixth portion 224F of the heat spreader 224 to upper surfaces of the first portion 224A, the second portion 224B, the third portion 224C, the fourth portion 224D and the fifth portion 224E of the heat spreader 224 and to an end of each of the memory stacks 230, 232, 234, 236. Advantageously, the heat spreader 224 surrounds and can contact a large portion of the memory stacks 230, 232, 234, 236 and can be adjacent and contact portions of the AI chiplets 210 in order to remove heat from all of those components.

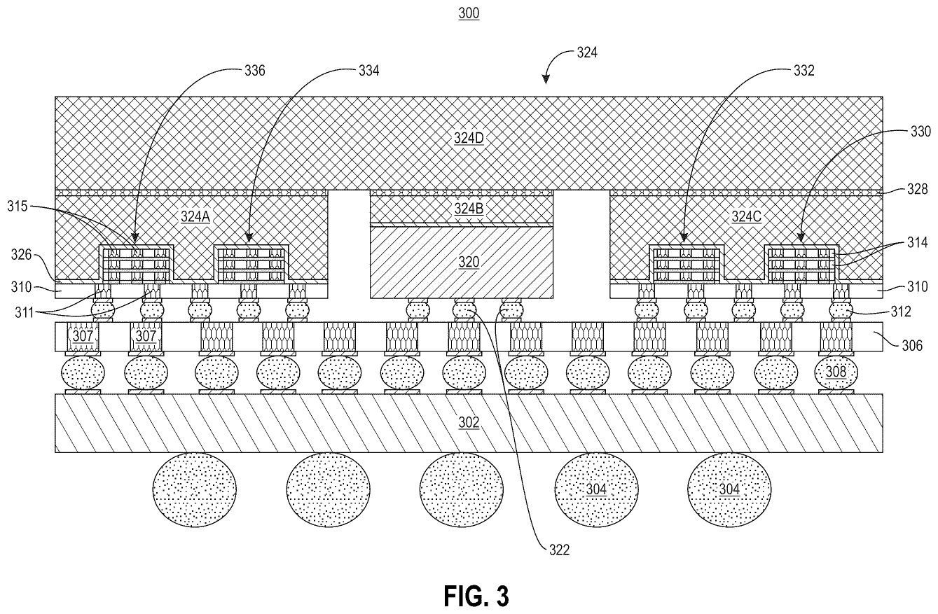

FIG. 3 illustrates a side cross-sectional view of an AI chiplet module with heat spreader 300, in accordance with embodiments of the present disclosure. The AI chiplet module with heat spreader 300, or semiconductor device, includes an organic substrate 302 that includes a first set of connectors 304 on its lower surface that can connect the AI chiplet module with heat spreader 300 to another component (not shown). A silicon interposer 306 is shown located above the organic substrate 302. The silicon interposer 306 is shown to include a plurality of TSVs 307. The TSVs 307 can be made of copper, for example. A second set of connectors 308 can be located between, and provided to connect, the silicon interposer 306 to the organic substrate 302.

On an upper surface of the silicon interposer 306, two (2) AI chiplets 310 are bonded to the silicon interposer 306 using connectors 312 and extend parallel to the silicon interposer 306. The AI chiplets 310 can include TSVs 311, as shown. The AI chiplets 310 generate a lot of heat. The AI chiplets 310 in the AI chiplet module with heat spreader 300 are increased in size, or extended, from the AI chiplets (such as 110, 210) in other embodiments, such as in FIGS. 1-2. There are two memory stacks that have each been divided or split into two smaller stacks creating four (4) smaller memory stacks 330, 332, 334, 336, including three (3) SRAMS 314 each, are located on an upper surface of one of the two (2) AI chiplets 310. The number of SRAMS 314 included, however, can be different from three (3) in number. The SRAMs 314 can include TSVs 315, as shown. The stacked SRAMs (the memory stacks 330, 332, 334, 336) of the embodiment, as compared to stacked SRAMs in other embodiments (of FIGS. 1-2), are separated into two parts. The memory stacks 330, 332, 334, 336 are connected to the AI chiplets 310 such that a horizontal plane running through the length of each of the memory stacks 330, 332, 334, 336 extends parallel to the horizontal plane of the AI chiplets 310. Between sets of two (2) of the memory stacks 330, 332, 334, 336, there is a hub 320 that can be connected to the silicon interposer 306 via a fourth set of connectors 322. The hub 320 can be a central device that connects several systems, subsystems, or networks together. The hub 320 can act as a switch that can redirect signals to other components on the AI chiplet module with heat spreader 300 and/or off-module.

A heat spreader 324 surrounds and directly contacts the memory stacks 330, 332, 334, 336 including the SRAMs 314. The heat spreader 324 can be applied or assembled in more than one part or portion. As shown, the heat spreader 324, in one example, can include a first portion 324A, a second portion 324B, a third portion 324C and a fourth portion 324D. The first portion 324A, the second portion 324B and the third portion 324C of the heat spreader 324 can be applied around the memory stacks 330, 332, 334, 336, with a TIM layer 326 being located (applied using a coating process) between both the AI chiplets 310 and the memory stacks 330, 332, 334, 336 and the first portion 324A, the second portion 324B, and the third portion 324C of the heat spreader 324. A layer of high thermal conductivity adhesive 328 (e.g., silver containing adhesive) can be applied using a coating process atop the first portion 324A, the second portion 324B and the third portion 324C of the heat spreader 324 and atop the memory stacks 330, 332, 334, 336 in order to adhere the fourth portion 324D of the heat spreader 324 to an upper surface of the first portion 324A, the second portion 324B, and the third portion 324C of the heat spreader 324 and to an end of the memory stacks 330, 332, 334, 336. Advantageously, the heat spreader 324 can surround and contact a large portion of the memory stacks 330, 332, 334, 336 and can be adjacent and can contact portions of the AI chiplets 310 in order to remove heat.

Embodiments of the present disclosure also include methods of forming the AI chiplet modules with heat spreaders (100, 200, 300) described herein. For example, an embodiment includes a method of forming the AI chiplet module with heat spreader 100 (in FIG. 1) that can include an operation of providing a substrate 102 having a first surface. The method can further include an operation of providing a silicon interposer 106 including a first surface and a second surface, wherein the first surface is connected to the first surface of the substrate 102. The method also includes an operation of bonding at least one stack 116, 118 including an AI chiplet 110 and a plurality of SRAMs 114 stacked below the AI chiplet 110, wherein the at least one stack 116, 118 includes a top surface, a bottom surface, a first side surface and a second side surface, and the at least one stack 116, 118 is orthogonally attached by the first side surface to the second surface of the silicon interposer 106. The method also includes an operation of attaching a heat spreader 124 (that can include multiple parts of the heat spreader 124, such as 124A-D) surrounding the top surface, the bottom surface and the second side surface of the at least one stack 116, 118 through a TIM layer 126 or the adhesive layer 128.

Another embodiment of the present disclosure is a method of forming the AI chiplet module with heat spreader 200 (in FIG. 2) that can include an operation of providing a substrate 202 having a first surface. The method can further include an operation of providing a silicon interposer 206 including a first surface and a second surface, wherein the first surface is connected to the first surface of the substrate 202. The method also includes an operation of increasing the size of AI chiplets 210 and connecting them to the second surface of the silicon interposer 206. The method includes another operation of bonding a plurality of stacks 230, 232, 234, 236 of a plurality of SRAMs 214, wherein the stacks 230, 232, 234, 236 include a top surface, a bottom surface, a first side surface and a second side surface. The stacks 230, 232, 234, 236 of SRAMs 214 are orthogonally bonded to the AI chiplets 210. The method also includes an operation of attaching a heat spreader 224 (that can include multiple parts of the heat spreader 224, such as 224A-F) surrounding the top surface, the bottom surface and the second side surface of the stacks 230, 232, 234, 236 and portions of the AI chiplets 210 through a TIM layer 226 or an adhesive layer 228.

Another embodiment of the present disclosure is a method of forming the AI chiplet module with heat spreader 300 (in FIG. 3) that can include an operation of providing a substrate 302 having a first surface. The method can further include an operation of providing a silicon interposer 306 including a first surface and a second surface, wherein the first surface is connected to the first surface of the substrate 302. The method also includes an operation of increasing the size of AI chiplets 310 and connecting them to the second surface of the silicon interposer 306. The method includes another operation of bonding a plurality of stacks 330, 332, 334, 336, each including a plurality of SRAMs 314, that are reduced in size compared to the stacks 230, 232, 234, 236 of FIG. 2. The stacks 330, 332, 334, 336 include a top surface, a bottom surface, a first side surface and a second side surface, and are bonded to the AI chiplets 310 by their bottom surfaces. The method also includes an operation of attaching a heat spreader 324 (that can include multiple parts of the heat spreader 324, such as 324A-D) surrounding the top surface, and the first and second side surfaces of the stacks 330, 332, 334, 336 and portions of the AI chiplets 310 through a TIM layer 326 or an adhesive 328.

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. An apparatus comprising:
a substrate having a first surface;
a silicon interposer including a first surface and a second surface, wherein the first surface is connected to the first surface of the substrate;
at least one stack including an artificial intelligence (AI) chiplet and a plurality of static random-access memories (SRAMs) stacked below the AI chiplet, wherein the at least one stack includes a top surface, a bottom surface, a first side surface and a second side surface, and the at least one stack is orthogonally attached by the first side surface to the second surface of the silicon interposer; and
a heat spreader surrounding the top surface, the bottom surface and the second side surface of the at least one stack.

2. The apparatus of claim 1, further comprising:
a hub chip connected to the second surface of the silicon interposer.

3. The apparatus of claim 1, wherein the silicon interposer includes a plurality of through-silicon vias (TSVs).

4. The apparatus of claim 1, wherein the AI chiplet includes a plurality of TSVs.

5. The apparatus of claim 1, wherein the plurality of SRAMs include a plurality of TSVs.

6. The apparatus of claim 1, wherein the heat spreader includes at least two separate portions that are connected using a layer of high thermal conductivity adhesive.

7. The apparatus of claim 1, further comprising:
a layer of thermal interface material (TIM) located between the heat spreader and the at least one stack.

8. An apparatus comprising:
a substrate having a first surface;
a silicon interposer including a first surface and a second surface, wherein the first surface is connected to the first surface of the substrate;
a plurality of artificial intelligence (AI) chiplets including a first surface and a second surface, wherein the first surface is connected to the second surface of the silicon interposer;
at least two stacks including a plurality of static random-access memories (SRAMs), wherein the at least two stacks include a top surface, a bottom surface, a first side surface and a second side surface, and the at least two stacks are orthogonally attached by the first side surface to the second surface of the plurality of AI chiplets; and
a heat spreader surrounding the top surface, the bottom surface and the second side surface of the at least two stacks.

9. The apparatus of claim 8, further comprising:
a hub chip connected to the second surface of the silicon interposer.

10. The apparatus of claim 8, wherein the silicon interposer includes a plurality of through-silicon vias (TSVs).

11. The apparatus of claim 8, wherein the plurality of AI chiplets include a plurality of TSVs.

12. The apparatus of claim 8, wherein the plurality of SRAMs include a plurality of TSVs.

13. The apparatus of claim 8, wherein the heat spreader includes at least two separate portions that are connected using a layer of high thermal conductivity adhesive.

14. The apparatus of claim 8, further comprising:
a layer of thermal interface material (TIM) located between the heat spreader and the at least two stacks.

15. An apparatus comprising:
a substrate having a first surface;
a silicon interposer including a first surface and a second surface, wherein the first surface is connected to the first surface of the substrate;
a plurality of artificial intelligence (AI) chiplets including a first surface and a second surface, wherein the first surface is connected to the second surface of the silicon interposer;
at least two stacks including a plurality of static random-access memories (SRAMs), wherein the at least two stacks are divided into two portions that include a top surface, a bottom surface, a first side surface and a second side surface, and the two portions of the at least two stacks are attached by the first side surface to the second surface of the plurality of AI chiplets; and
a heat spreader surrounding the top surface, the bottom surface and the second side surface of the two portions of the at least two stacks.

16. The apparatus of claim 15, further comprising:
a hub chip connected to the second surface of the silicon interposer.

17. The apparatus of claim 15, wherein the plurality of AI chiplets include a plurality of through-silicon vias (TSVs).

18. The apparatus of claim 15, wherein the plurality of SRAMs include a plurality of TSVs.

19. The apparatus of claim 15, wherein the heat spreader includes at least two separate portions that are connected using a layer of high thermal conductivity adhesive.

20. The apparatus of claim 15, further comprising:
a layer of thermal interface material (TIM) located between the heat spreader and the at least two stacks.
